(19) United States
(12) Patent Application Publication
(10) Pub. No.: US 2017/0148918 A1
(43) Pub. Date: May 25, 2017

(54) MATERIALS FOR TENSILE STRESS AND LOW CONTACT RESISTANCE AND METHOD OF FORMING

(71) Applicant: Applied Materials, Inc., Santa Clara, CA (US)

(72) Inventors: Zhiyuan YE, San Jose, CA (US); Xinyu BAO, Fremont, CA (US); Errol Antonio C. SANCHEZ, Tracy, CA (US); Xuebin LI, Sunnyvale, CA (US)

(21) Appl. No.: 15/350,967

(22) Filed: Nov. 14, 2016

Related U.S. Application Data
(60) Provisional application No. 62/259,869, filed on Nov. 25, 2015.
(60) Provisional application No. 62/280,594, filed on Jan. 19, 2016.

(51) Int. Cl. H01L 29/78; H01L 29/24; H01L 29/66; H01L 21/02; H01L 29/08

(52) U.S. Cl. CPC H01L 29/7849; H01L 21/02521; H01L 21/0262; H01L 21/02658; H01L 29/0847; H01L 29/66477; H01L 29/24

(57) ABSTRACT

The present disclosure generally relate to methods for forming an epitaxial layer on a semiconductor device, including a method of forming a tensile-stressed germanium arsenic layer. The method includes heating a substrate disposed within a processing chamber, wherein the substrate comprises silicon, and exposing a surface of the substrate to a germanium-containing gas and an arsenic-containing gas to form a germanium arsenic alloy having an arsenic concentration of 4.5×10²⁰ atoms per cubic centimeter or greater on the surface.

### CROSS-REFERENCE TO RELATED APPLICATIONS

This application claims priority to U.S. provisional patent application Ser. No. 62/259,869, filed Nov. 25, 2015, and 62/280,594, filed Jan. 19, 2016, which are herein incorporated by reference.

### FIELD

Implementations of the disclosure generally relate to the field of semiconductor manufacturing processes and devices, more particularly, to methods for epitaxial growth of a silicon material on an epitaxial film.

### BACKGROUND

Microelectronic devices are fabricated on a semiconductor substrate as integrated circuits in which various conductive layers are interconnected with one another to permit electronic signals to propagate within the device. An example of such a device is a complementary metal-oxide-semiconductor (CMOS) field effect transistor (FET) or MOSFET. Typical MOSFET transistors may include p-channel (PMOS) transistors and n-channel MOS (NMOS) transistors, depending on the dopant conductivity types, whereas the PMOS has a p-type channel, i.e., holes are responsible for conduction in the channel, and the NMOS has an n-type channel, i.e., the electrons are responsible for conduction in the channel.

The amount of current that flows through the channel of a MOS transistor is directly proportional to a mobility of carriers in the channel. The use of high mobility MOS transistors enables more current to flow and consequently faster circuit performance. Mobility of the carriers in the channel of an MOS transistor can be increased by producing a mechanical stress in the channel. A channel under compressive strain, for example, a silicon-germanium channel layer grown on silicon, has significantly enhanced hole mobility to provide a pMOS transistor. A channel under tensile strain, for example, a thin silicon channel layer grown on relaxed silicon-germanium, achieves significantly enhanced electron mobility to provide an nMOS transistor.

An nMOS transistor channel under tensile strain can also be provided by forming one or more heavily phosphorus-doped silicon epitaxial layers or heavily carbon-doped silicon epitaxial layers. Heavily doped silicon epitaxial layers can be used to reduce the contact resistance. Contact resistance becomes the major limiting factor of transistor performance in the recent and future nodes due to the fact that the manufacturing conditions may be different for epitaxy having different dopants and dopant concentrations. For example, diffusion control of high strain Si:P epitaxy when activating and to achieve high levels of dopants (e.g., greater than 4×10²¹ atoms/cm³) has been a major challenge due to morphology degradation. Also, incorporating dopants into new materials, such as Ge or GeSn, for strain purpose may pose significant challenges in the epitaxial processing.

Therefore, improved methods for providing tensile stress in the channel and providing low series resistance are in the art.

### SUMMARY

In one implementation, a method of forming a tensile-stressed germanium arsenic layer is provided. The method includes heating a substrate disposed within a processing chamber, wherein the substrate comprises silicon, and exposing a surface of the substrate to a germanium-containing gas and an arsenic-containing gas to form a germanium arsenic alloy having an arsenic concentration of 4.5×10²¹ to 5×10²⁰ atoms per cubic centimeter or greater on the surface.

In another implementation, a method for processing a substrate is provided. The method includes positioning a semiconductor substrate in a processing chamber, wherein the substrate comprises a source/drain region, exposing the substrate to a silicon-containing gas and an arsenic-containing gas to form a silicon arsenic alloy having an arsenic concentration of 4.5×10²¹ to 5×10²¹ atoms per cubic centimeter or greater on the source/drain region, wherein the silicon arsenic alloy has a carbon concentration of about 1×10¹⁷ to about 1×10²⁰ atoms per cubic centimeter or greater, and forming a transistor channel region on the silicon arsenic alloy.

In yet another implementation, a structure is provided. The structure includes a substrate comprising a source region and a drain region, a channel region disposed between the source region and the drain region, a source drain extension region disposed laterally outward of the channel region, wherein the source drain extension region is a silicon arsenic alloy having an arsenic concentration of 4.5×10²¹ to 5×10²¹ atoms per cubic centimeter or greater and a carbon concentration of about 1×10¹⁷ atoms per cubic centimeter or greater; and a gate region disposed above the channel region.

In one yet another embodiment, a method of forming a germanium phosphide layer is provided. The method includes heating a substrate disposed within a processing chamber having a chamber pressure of about 10 Torr to about 100 Torr, exposing a surface of the substrate to a germanium-containing gas and a phosphorus-containing gas at a temperature of about 400 degrees Celsius or lower to form a germanium phosphide alloy having a phosphorus concentration of 7.5×10¹⁹ atoms per cubic centimeter or greater on the surface, wherein the phosphorus-containing gas is introduced into the processing chamber at a partial pressure of about 3 Torr to about 30 Torr.

### BRIEF DESCRIPTION OF THE DRAWINGS

Implementations of the present disclosure, briefly summarized above and discussed in greater detail below, can be understood by reference to the illustrative implementations of the disclosure depicted in the appended drawings. It is to be noted, however, that the appended drawings illustrate only typical implementations of this disclosure and are therefore not to be considered limiting of its scope, for the disclosure may admit to other equally effective implementations.

FIG. 1 is a flow chart illustrating a method of forming an epitaxial layer according to one implementation of the present disclosure.

FIG. 2 illustrates a structure manufactured according to method of FIG. 1.

FIG. 3A is a flow chart illustrating a method of forming an epitaxial layer according to another implementation of the present disclosure.

FIG. 3B is a cross-sectional view of a structure manufactured according to implementations of the present disclosure.

FIG. 4 is a flow chart illustrating a method of forming a high quality germanium phosphide (GeP) epitaxial layer according to one implementation of the present disclosure.

To facilitate understanding, identical reference numerals have been used, where possible, to designate identical elements that are common to the figures. The figures are not drawn to scale and may be simplified for clarity. It is contemplated that elements and features of one implementation may be beneficially incorporated in other implementations without further recitation.

### DETAILED DESCRIPTION

Implementations of the present disclosure generally provide selective epitaxy processes for silicon, germanium, or germanium-tin layer having high arsenic concentration. In one exemplary implementation, the selective epitaxy process uses a gas mixture comprising germanium source and a arsenic dopant source, and is performed at increased process pressures above 300 Torr and reduced process temperatures below 800 degrees Celsius to allow for formation of a tensile-stressed epitaxial germanium layer having an arsenic concentration of 4.5×10²¹ to 5×10²⁰ atoms per cubic centimeter or greater. A arsenic concentration of about 5×10²⁰ atoms per cubic centimeter or greater results in increased carrier mobility and improved device performance for MOSFET structures. Various implementations are discussed in more detail below.

Implementations of the present disclosure may be practiced in the CENTURA® RP Epi chamber available from Applied Materials, Inc., of Santa Clara, Calif. It is contemplated that other chambers, including those available from other manufacturers, may be used to practice implementations of the disclosure.

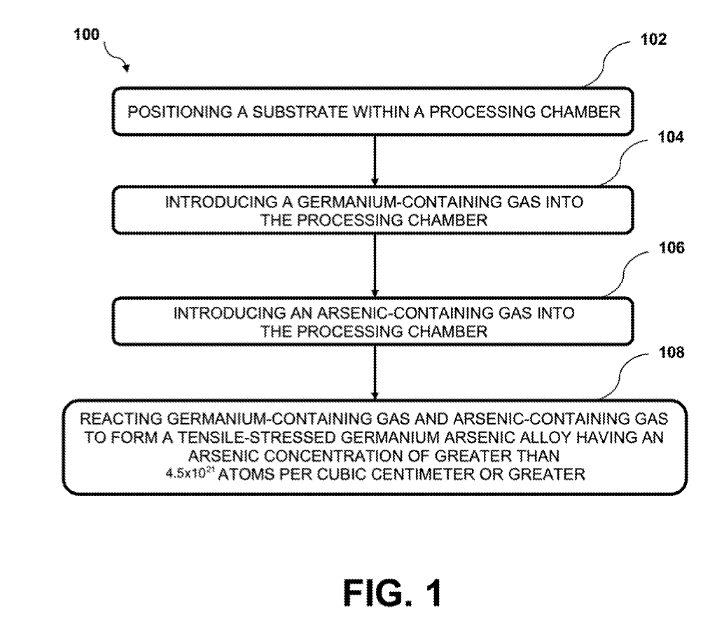

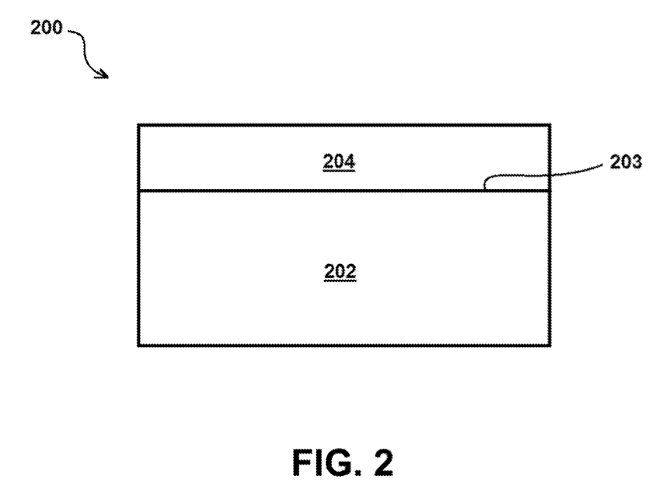

FIG. 1 is a flow chart 100 illustrating a method of forming an epitaxial layer according to one implementation of the present disclosure. FIG. 2 illustrates a cross-sectional view of a structure 200 manufactured according to method of FIG. 1. At box 102, a substrate 202 is positioned within a processing chamber. The term “substrate” used herein is intended to broadly cover any object or material having a surface onto which a material layer can be deposited. A substrate may include a bulk material such as silicon (e.g., single crystal silicon which may include dopants) or may include one or more layers overlying the bulk material. The substrate may be a planar substrate or a patterned substrate. Patterned substrates are substrates that may include electronic features formed into or onto a processing surface of the substrate. The substrate may contain monocrystalline surfaces and/or one secondary surface that is non-monocrystalline, such as polycrystalline or amorphous surfaces. Monocrystalline surfaces may include the bare crystalline substrate or a deposited single crystal layer usually made from a material such as silicon, germanium, silicon germanium or silicon carbon. Polycrystalline or amorphous surfaces may include dielectric materials, such as oxides or nitrides, specifically silicon oxide or silicon nitride, as well as amorphous silicon surfaces.

Positioning the substrate in the processing chamber may include adjusting one or more reactor conditions, such as temperature, pressure, and/or carrier gas (e.g., Ar, N₂, H₂, or He) flow rate, to conditions suitable for film formation. For example, in some implementations, the temperature in the processing chamber may be adjusted so that a reaction region formed at or near an exposed silicon surface of the substrate, or that the surface of the substrate itself, is about 850 degrees Celsius or less, for example about 750 degrees Celsius or less. In one example, the substrate is heated to a temperature of about 200 degrees Celsius to about 800 degrees Celsius, for example about 250 degrees Celsius to about 650 degrees Celsius, such as about 300 degrees Celsius to about 600 degrees Celsius. It is possible to minimize the thermal budget of the final device by heating the substrate to the lowest temperature sufficient to thermally decompose process reagents and deposit a layer on the substrate. The pressure in the processing chamber may be adjusted so that the reaction region pressure is within range of about 1 to about 760 Torr, for example about 90 to about 300 Torr. In some implementations, a carrier (e.g., nitrogen) gas may be flowed into the processing chamber at a flow rate of appreciated that in some implementations, a different carrier/diluent gas may be approximately 10 to 40 SLM (standard liters per minute). However, it will be employed, a different flow rate may be used, or that such gas(es) may be omitted.

At box 104, a germanium-containing gas is introduced into the processing chamber. Suitable germanium-containing gas may include, but is not limited to germane (GeH₄), digermane (Ge₂H₆), trigermane (Ge₃H₆), chlorinated germane gas such as germanium tetrachloride (GeCl₄), dichlorogermane (GeH₂Cl₂), trichlorogermane (GeHCl₃), hexachlorodigermane (Ge₂Cl₆), or a combination of any two or more thereof. Any suitable halogenated germanium compounds may also be used. In one example where germane is used, germane may be flowed into the processing chamber at a flow rate of approximately 5 sccm to about 100 sccm, for example about 10 sccm to about 35 sccm, such as about 15 sccm to about 25 sccm, for example about 20 sccm. In some implementations, germane may be flowed into the processing chamber at a flow rate of about 300 sccm to about 1500 sccm, for example about 800 sccm.

At box 106, an arsenic-containing gas is introduced into the processing chamber. Suitable arsenic-containing gas may include arsine (AsH₃) or Tertiary butyl arsine (TBAs). In some implementations, a carbon-containing compound may be introduced into the processing chamber. For example, when AsH₃ is used as arsenic source, the carbon-containing compound may be used to add carbon in the deposited epitaxial layer. Exemplary carbon-containing compound may include, but is not limited to monomethyl silane (MMS), tetramethyl silane (TMS), or metal organic precursor such as tributyl arsenide (TBAs).

In one implementation, arsine is introduced into the processing chamber at a flow rate of approximately 10 sccm to about 2500 sccm, for example about 500 sccm to about 1500 sccm. The carbon-containing compound is introduced into the processing chamber at a flow rate of approximately 10 sccm to about 2500 sccm, for example about 500 sccm to about 1500 sccm. A non-reactive carrier/diluent gas (e.g., nitrogen) and/or a reactive carrier/diluent gas (e.g., hydrogen) may be used to supply the arsenic-containing gas and/or carbon-containing compound to the processing chamber. For example, arsine may be diluted in hydrogen at a ratio of about one percent. The carrier/diluent gas may have a flow rate from about 1 SLM to about 100 SLM, such as from about 3 SLM to about 30 SLM.

It is contemplated that boxes 104 and 106 may occur simultaneously, substantially simultaneously, or in any desired order. In addition, while arsenic-containing gas is discussed in this disclosure, it is contemplated that any gas consisting of dopant atoms having diffusion coefficients less than the diffusion coefficient of the phosphorous atoms in silicon may be used induce stress in the silicon lattice structure. In one implementation where the substrate is formed of GeSn, an antimony-containing gas, such as Triethyl antimony (TESb), may be used to induce stress in GeSn.

If desired, one or more dopant gases may be introduced into the processing chamber to provide the epitaxial layer with desired conductive characteristic and various electric characteristics, such as directional electron flow in a controlled and desired pathway required by the electronic device. Exemplary dopant gas may include, but are not limited to phosphorous, boron, gallium, or aluminum, depending upon the desired conductive characteristic of the deposited epitaxial layer.

At box 108, the mixture of germanium-containing gas and the arsenic-containing gas is thermally reacted to form a tensile-stressed germanium arsenic alloy having an arsenic concentration of greater than 4.5×10²⁰ atoms per cubic centimeter or greater, for example 4.5×10²¹ to 5×10²° atoms per cubic centimeter or greater, within an acceptable tolerance of ±3%. In some implementations, the tensile-stressed germanium arsenic alloy may have an arsenic concentration as high as 5×10²¹ atoms per cubic centimeter.

The germanium source and the arsenic source may react in a reaction region of the processing chamber so that the germanium arsenic alloy 204 is epitaxially formed on a silicon surface 203 of the substrate 202. The germanium arsenic alloy 204 may have a thickness of about 250 Å to about 800 Å, for example about 500 Å. Not wishing to be bound by theory, it is believed that at an arsenic concentration of about 4.5×10²⁰ atoms per cubic centimeter or greater, for example about 4.5×10²¹ to 5×10²¹ atoms per cubic centimeter or greater, the deposited epitaxial film is not purely a germanium film doped with arsenic, but rather, that the deposited film is an alloy between silicon and germanium arsenic (e.g., pseudocubic Ge₃As₄). Germanium arsenic alloy generates stabilized vacancy in silicon lattice that would expel silicon atoms from the lattice structure, which in turn collapses the silicon lattice structure and thus forms a zoned stress in the epitaxial film. A tensile-stressed epitaxial germanium layer having an arsenic concentration of 5×10²¹ atoms per cubic centimeter or greater can improve transistor performance because stress distorts (e.g., strains) the semiconductor crystal lattice, and the distortion, in turn, affects charge transport properties of the semiconductor. As a result, carrier mobility in the transistor channel region is increased. By controlling the magnitude of stress in a finished device, manufacturers can increase carrier mobility and improve device performance.

During the epitaxy process, the temperature within the processing chamber is maintained at about 450 degrees Celsius to about 800 degrees Celsius, for example about 600 degrees Celsius to about 750 degrees Celsius, such as about 650 degrees Celsius to about 725 degrees Celsius. The pressure within the processing chamber is maintained at about 1 Torr or greater, for example, about 10 Torr or greater, such as about 150 Torr to about 600 Torr. It is contemplated that pressures greater than about 600 Torr may be utilized when low pressure deposition chambers are not employed. In contrast, typical epitaxial growth processes in low pressure deposition chambers maintain a processing pressure of about 10 Torr to about 100 Torr and a processing temperature greater than 600 degrees Celsius. However, it has been observed that by increasing the pressure to about 150 Torr or greater, for example about 300 Torr or greater, the deposited epitaxial film can be formed with a greater arsenic concentration (e.g., about 1×10²¹ atoms per cubic centimeter to about 5×10²² atoms per cubic centimeter) as compared to lower pressure epitaxial growth processes.

It should be noted that the concept described in implementations of the present disclosure is also applicable to other materials that may be used in logic and memory applications. Some example may include SiGeAs, GeP, SiGeP, SiGeB, Si:CP, GeSn, GeP, GeB, or GeSnB that are formed as an alloy. In any case, the doping level may exceed solid solubility in the epitaxial layer, for example above 5×10²⁰, or about 1% or 2% dopant level.

In addition, although epitaxy process is discussed in this disclosure, it is contemplated that other process, such as As implantation process, may also be used to form a tensile-stressed silicon arsenic or germanium arsenic layer. In case where implantation process is utilized, an annealing process running at about 600 degrees Celsius or higher, for example about 950 degrees Celsius, may be performed after the implantation process to stabilize or repair any damages in the lattice structure caused by the implantation process. Anneal processes can be carried out using laser anneal processes, spike anneal processes, or rapid thermal anneal processes. The lasers may be any type of laser such as gas laser, excimer laser, solid-state laser, fiber laser, semiconductor laser etc., which may be configurable to emit light at a single wavelength or at two or more wavelengths simultaneously. The laser anneal process may take place on a given region of the substrate for a relatively short time, such as on the order of about one second or less. In one implementation, the laser anneal process is performed on the order of millisecond. Millisecond annealing provides improved yield performance while enabling precise control of the placement of atoms in the deposited epitaxial layer. Millisecond annealing also avoids dopant diffusion or any negative impact on the resistivity and the tensile strain of the deposited layer.

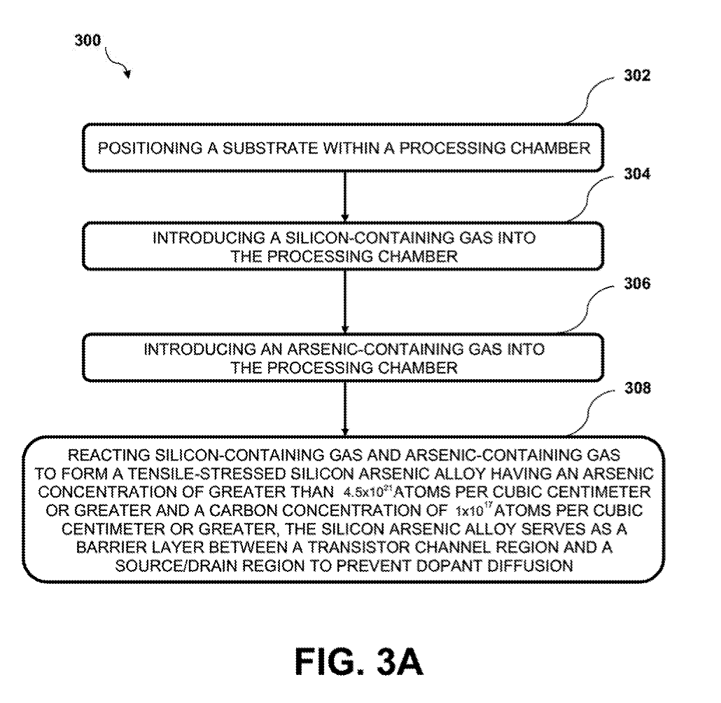

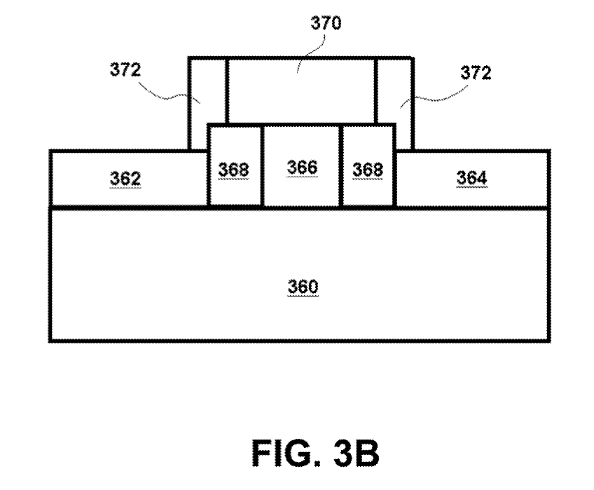

FIG. 3A is a flow chart 300 illustrating a method of forming an epitaxial layer according to another implementation of the present disclosure. At box 302, a substrate is positioned within a processing chamber. One or more reactor conditions may be adjusted in a similar manner as discussed above with respect to box 102.

At box 304, a silicon-containing gas is introduced into the processing chamber. Suitable silicon-containing gas may include, but is not limited to, silanes, halogenated silanes, or combinations thereof. Silanes may include silane (SiH₄) and higher silanes with the empirical formula SiₓH₍₂ₓ₊₂₎, such as disilane (Si₂H₆), trisilane (Si₃H₈), and tetrasilane (Si₄H₁₀). Halogenated silanes may include monochlorosilane (MCS), dichlorosilane (DCS), trichlorosilane (TCS), hexachlorodisilane (HODS), octachlorotrisilane (OCTS), silicon tetrachloride (STC), or any combination thereof. In one implementation, the silicon-containing gas is disilane. In another implementation, the silicon source comprises TCS. In yet another implementation, the silicon source comprises TCS and DCS. In one example where disilane is used, disilane may be flowed into processing chamber at a flow rate of approximately 200 sccm to about 1500 sccm, for example about 500 sccm to about 1000 sccm, such as about 700 sccm to about 850 sccm, for example about 800 sccm.

At box 306, an arsenic-containing gas is introduced into the processing chamber. Suitable arsenic-containing gas may include Tertiary butyl arsine (TBAs) or arsine (AsH₃). In some implementations, a carbon-containing compound may be introduced into the processing chamber. For example, when AsH₃ is used as arsenic source, the carbon-containing compound may be used to add carbon in the deposited epitaxial layer. Exemplary carbon-containing compound may include, but is not limited to monomethyl silane (MMS), tetramethyl silane (TMS), or metal organic precursor such as tributyl arsenide (TBAs). In one implementation, TBAs is introduced into the processing chamber at a flow rate of approximately 10 sccm to about 200 sccm, such as about 20 sccm to about 100 sccm, for example about 75 sccm to about 85 sccm.

It is contemplated that boxes 304 and 306 may occur simultaneously, substantially simultaneously, or in any desired order. In addition, while arsenic-containing gas is discussed in this disclosure, it is contemplated that any gas consisting of dopant atoms having diffusion coefficients less than the diffusion coefficient of the phosphorous atoms in silicon may be used induce stress in the silicon lattice structure. For example, an antimony-containing gas, such as Triethyl antimony (TESb), may be used to replace, or in addition to, the arsenic-containing gas.

If desired, one or more dopant gases may be introduced into the processing chamber to provide the epitaxial layer with desired conductive characteristic and various electric characteristics, such as directional electron flow in a controlled and desired pathway required by the electronic device. Exemplary dopant gas may include, but are not limited to phosphorous, boron, gallium, or aluminum, depending upon the desired conductive characteristic of the deposited epitaxial layer.

At box 308, the mixture of silicon-containing gas and the arsenic-containing gas is thermally reacted to form a tensile-stressed silicon arsenic alloy having an arsenic concentration of greater than 4.5×10²⁰ atoms per cubic centimeter or greater, for example 4.5×10²¹ to 5×10²¹ atoms per cubic centimeter or greater, within an acceptable tolerance of ±3%. Particularly, the silicon arsenic alloy contains carbons from TESb. In one implementation, the silicon arsenic alloy has a carbon concentration of about 1×10¹⁷ atoms per cubic centimeter or greater, for example about 1×10¹⁸ to 1×10²⁰ atoms per cubic centimeter. The deposited silicon arsenic alloy may have a thickness of about 250 Å to about 800 Å, for example about 500 Å.

Similarly, the silicon source and the arsenic source may react in a reaction region of the processing chamber so that the silicon arsenic alloy is epitaxially formed. It is believed that at an arsenic concentration of about 4.5×10²⁰ atoms per cubic centimeter or greater, for example about 4.5×10²¹ to 5×10²¹ atoms per cubic centimeter or greater, the deposited epitaxial film is not purely a silicon film doped with arsenic, but rather, that the deposited film is an alloy between silicon and silicon arsenic (e.g., pseudocubic Si₃As₄). A tensile-stressed epitaxial silicon layer having an arsenic concentration of 5×10²¹ atoms per cubic centimeter or greater can also improve transistor performance because stress distorts (e.g., strains) the semiconductor crystal lattice, and the distortion, in turn, affects charge transport properties of the semiconductor.

During the epitaxy process, the temperature within the processing chamber is maintained at about 400 degrees Celsius to about 800 degrees Celsius, for example about 600 degrees Celsius to about 750 degrees Celsius, such as about 625 degrees Celsius to about 700 degrees Celsius. The pressure within the processing chamber is maintained at about 1 Torr to about 150 Torr, for example, about 10 Torr to about 20 Torr. In one implementation, the tensile-stressed epitaxial silicon layer is formed using disliane and TBAs at a temperature of 600 degrees Celsius and 20 Torr. Depending upon the silicon source used, it is contemplated that pressures greater than about 150 Torr may be utilized. In addition, by increasing the pressure to about 150 Torr or greater, for example about 300 Torr or greater, the deposited epitaxial film can be formed with a greater arsenic concentration (e.g., about 5×10²¹ atoms per cubic centimeter or above) as compared to lower pressure epitaxial growth processes.

The silicon arsenic alloy may serve as a diffusion barrier layer presented near a transistor channel between source and drain regions in a semiconductor device, such as a metal-oxide-semiconductor field-effect transistor (MOSFET) or a FinFET (Fin field-effect transistor) in which the channel connecting the source and drain regions is a thin “fin” jutting out of a substrate. This is because carbons in the deposited epitaxial film can prevent or slow down diffusion of phosphorus (or other dopants) from source/drain regions into the channel region during a high temperature (e.g., above 800 degrees Celsius) operation. Such dopant diffusion disadvantageously contributes to leakage currents and poor breakdown performance.

An exemplary structure that may be benefit from the implementations of the present disclosure is schematically shown in FIG. 3B, which is a cross-sectional view of a FinFET structure 358. It should be noted that the structure 358 is merely exemplary and not drawn to scale. Therefore, the implementations of the present disclosure should not be limited to the structure 358 as shown. In one implementation, the structure 358 includes a substrate 360, a Si:P source region 362 and a Si:P drain region 364 formed above the substrate 360. An channel region 366 (doped or undoped) is disposed between the Si:P source region 362 and the Si:P drain region 364. A source drain extension (SDE) region 368, which is a carbon-doped silicon arsenic alloy formed according to the implementations of the present disclosure, is disposed between the Si:P source region 362 and the Si:P drain region 364 to act us P diffusion blocker. The source drain extension (SDE) region 368 may be disposed near or against both sides of the channel region (e.g., laterally outward of the channel region 366). A gate 370 is formed on top and around the channel region 366. A spacer 372 may be formed around the gate 370 on top of the SDE region 368.

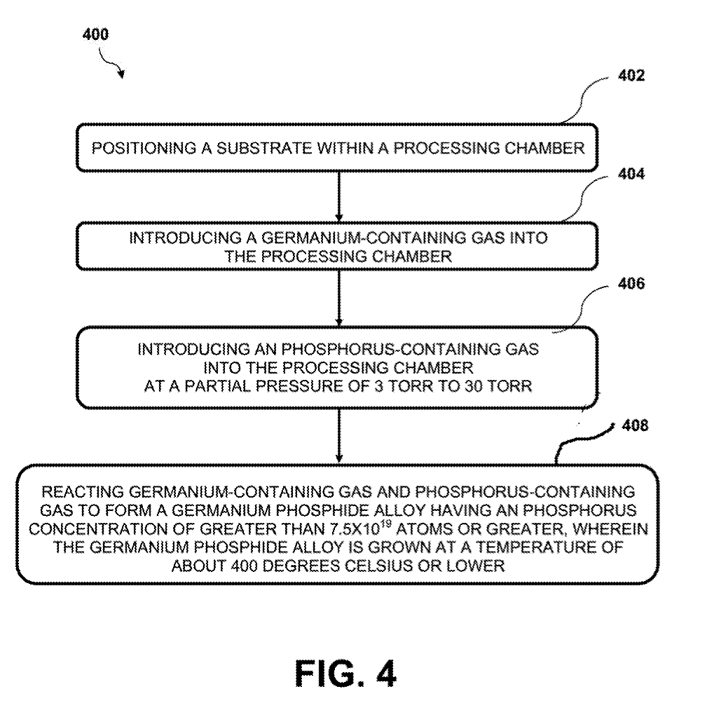

FIG. 4 is a flow chart 400 illustrating a method of forming a high quality germanium phosphide (GeP) epitaxial material according to one implementation of the present disclosure. At box 402, a substrate is positioned within a processing chamber. One or more reactor conditions may be adjusted in a similar manner as discussed above with respect to box 102.

The term “substrate” used herein is intended to broadly cover any object or material having a surface onto which a material layer can be deposited. A substrate may include a bulk material such as silicon (e.g., single crystal silicon which may include dopants) or may include one or more layers overlying the bulk material. The substrate may be a planar substrate or a patterned substrate. Patterned substrates are substrates that may include electronic features formed into or onto a processing surface of the substrate. The substrate may contain monocrystalline surfaces and/or one secondary surface that is non-monocrystalline, such as polycrystalline or amorphous surfaces. Monocrystalline surfaces may include the bare crystalline substrate or a deposited single crystal layer usually made from a material such as silicon, germanium, silicon germanium or silicon carbon. Polycrystalline or amorphous surfaces may include dielectric materials, such as oxides or nitrides, specifically silicon oxide or silicon nitride, as well as amorphous silicon surfaces.

At box 404, a germanium-containing gas is introduced into the processing chamber. Suitable germanium-containing gas may include, but is not limited to germane (GeH₄), digermane (Ge₂H₆), trigermane (Ge₃H₈), chlorinated germane gas such as germanium tetrachloride (GeCl₄), dichlorogermane (GeH₂Cl₂), trichlorogermane (GeHCl₃), hexachlorodigermane (Ge₂Cl₆), or a combination of any two or more thereof. Any suitable halogenated germanium compounds may also be used. In one exemplary implementation, digermane (Ge₂H₆) is used. Digermane is found to be advantageous to incorporate Ge efficiently in the lattice for the very low temperature epitaxy of Ge alloys due to its reactivity at low temperatures. As a result, high growth rate can be obtained at low temperatures such as 400 degrees Celsius or lower, for example 350 400 degrees Celsius.

In one exemplary example where digermane (Ge₂H₆) is used, digermane may be flowed into the processing chamber at a flow rate of approximately 5 sccm to about 100 sccm, for example between about 10 sccm and about 95 sccm, such as about 15 sccm to about 25 sccm, such as about 25 sccm to about 35 sccm, such as about 35 sccm to about 45 sccm, such as about 45 sccm to about 55 sccm, such as about 55 sccm to about 65 sccm, such as about 65 sccm to about 75 sccm, such as about 75 sccm to about 85 sccm, such as about 85 sccm to about 95 sccm. In one implementation, digermane is flowed into the processing chamber at a flow rate of about 20 sccm. Higher flow rate is also contemplated. For example, digermane may be flowed into the processing chamber at a flow rate of about 300 sccm to about 1500 sccm, for example about 800 sccm.

At box 406, a phosphorus-containing gas is introduced into the processing chamber. One exemplary phosphorus-containing gas is tertiary butyl phosphine (TBP). Another exemplary phosphorus-containing gas includes phosphine (PH₃). In one implementation, TBP or phosphine may be introduced into the processing chamber at a flow rate of approximately 10 sccm to about 200 sccm, such as between about 10 sccm to about 20 sccm, about 20 sccm to about 30 sccm, about 30 sccm to about 40 sccm, about 40 sccm to about 50 sccm, about 50 sccm to about 60 sccm, about 60 sccm to about 70 sccm, about 70 sccm to about 80 sccm, about 80 sccm to about 90 sccm, about 90 sccm to about 100 sccm, about 100 sccm to about 110 sccm, about 110 sccm to about 120 sccm, about 120 sccm to about 130 sccm, about 130 sccm to about 140 sccm, about 140 sccm to about 150 sccm, about 150 sccm to about 160 sccm, about 160 sccm to about 170 sccm, about 170 sccm to about 180 sccm, about 180 sccm to about 190 sccm, about 190 sccm to about 200 sccm.

It is contemplated that boxes 404 and 406 may occur simultaneously, substantially simultaneously, or in any desired sequence. In addition, while phosphorus-containing gas is discussed in this disclosure, it is contemplated that any gas consisting of dopant atoms having diffusion coefficients less than the diffusion coefficient of the phosphorous atoms in silicon may be used to induce stress in the silicon lattice structure. For example, an arsenic-containing gas, such as Tertiary butyl arsine (TBAs) or arsine (AsH₃), an antimony-containing gas, such as Triethyl antimony (TESb), may be used to replace, or in addition to, the phosphorus-containing gas, depending upon the desired properties and/or conductive characteristic of the deposited epitaxial layer.

At box 408, the mixture of germanium-containing gas and the phosphorus-containing gas is thermally reacted to epitaxially grow a germanium phosphide (GeP) alloy or material on the substrate.

During the epitaxy process, the temperature within the processing chamber is maintained at about 450 degrees Celsius or less, for example about 150 degree to 400 degrees Celsius, for example about 200 degrees Celsius to about 250 degrees Celsius, about 250 degrees Celsius to about 300 degrees Celsius, about 300 degrees Celsius to about 350 degrees Celsius, about 350 degrees Celsius to about 400 degrees Celsius. In one implementation, the germanium phosphide alloy is grown at a temperature of about 350 degrees Celsius. The pressure within the processing chamber is maintained at about 1 Torr to about 150 Torr, for example, about 10 Torr to about 100 Torr, for example 100 Torr. It is contemplated that pressures greater than about 100 Torr may be utilized to obtain a greater phosphorus concentration as compared to lower pressure epitaxial growth processes.

In one implementation where digermane and phosphine were used, the phosphine partial pressure may be in the range of 3 Torr to about 30 Torr. The mole ratio of P to Ge may be between about 1:10 and about 1:40, for example about 1:20 to about 1:30. It has been observed that the GeP alloy formed under the parameters described herein shows high crystalline quality with very high P⁺ions concentrations. For example, the GeP alloy formed under the parameters described herein has been observed to contain a high phosphorus concentration of about 7.5×10¹⁹ atoms per cubic centimeter or greater, for example 4.5×10²⁰ atoms per cubic centimeter or greater, for example 4.5×10²¹ to 5×10²¹ atoms per cubic centimeter or greater, within an acceptable tolerance of ±3%. The deposited germanium phosphide alloy may have a thickness of about 250 Å to about 800 Å, for example about 500 Å.

Benefits of the present disclosure include a tensile-stressed germanium arsenic layer having an arsenic doping level of greater than 5×10²⁰ to atoms per cubic centimeter or greater to improve transistor performance. Heavily arsenic doped germanium can result in significant tensile strain in germanium or other materials suitable for use in logic and memory applications. The increased stress distorts or strains the semiconductor crystal lattice, and the distortion, in turn, affects charge transport properties of the semiconductor. As a result, carrier mobility is increased and device performance is therefore improved. In some implementations, a heavily arsenic doped silicon may contain carbon at a concentration of 1×10¹⁷ to 1×10²⁰ atoms per cubic centimeter or greater to prevent diffusion of phosphorus (or other dopants) from source/drain regions into a channel region during a high temperature operation. Therefore, leakage current occurred at the channel region is minimized or avoided.

Benefits of the present disclosure also include a very low temperature growth of high quality Ge:P using digermane (Ge₂H₆) and phosphine (PH₃). The epitaxy process is performed in a reduced pressure of about 100 Torr, with phosphine partial pressure in the range of 3 Torr to about 30 Torr to obtain a high phosphorus concentration of 7.5×10¹⁹ atoms per cubic centimeter or greater. The high phosphorus concentration induces stress within the deposited epitaxial film, thereby increasing tensile strain, leading to increased carrier mobility and improved device performance.

While the foregoing is directed to implementations of the present disclosure, other and further implementations of the disclosure may be devised without departing from the basic scope thereof.

1. A method of forming a tensile-stressed germanium arsenic layer, comprising:
heating a substrate disposed within a processing chamber, wherein the substrate comprises silicon; and
exposing a surface of the substrate to a germanium-containing gas and an arsenic-containing gas to form a germanium arsenic alloy having an arsenic concentration of 4.5×10²⁰ atoms per cubic centimeter or greater on the surface.

2. The method of claim 1, wherein the germanium-containing gas comprises germane (GeH₄), digermane (Ge₂H₆), trigermane (Ge₃H₈), germanium tetrachloride (GeCl₄), dichlorogermane (GeH₂Cl₂), trichlorogermane (GeHCl₃), hexachloro-digermane (Ge₂Cl₆), or any combination thereof.

3. The method of claim 1, wherein the arsenic-containing gas comprises arsine (AsH₃) or Tertiary butyl arsine (TBAs).

4. The method of claim 1, wherein the germanium arsenic alloy has an arsenic concentration of at least 4.5×10²¹ to 5×10²¹ atoms per cubic centimeter.

5. The method of claim 4, wherein exposing a surface of the substrate to a germanium-containing gas and an arsenic-containing gas comprises maintaining a temperature within the processing chamber of about 450 degrees Celsius to about 800 degrees Celsius.

6. The method of claim 1, wherein the pressure within the processing chamber is maintained at about 10 Torr or greater.

7. A method of processing a substrate, comprising:
positioning a semiconductor substrate in a processing chamber, wherein the substrate comprises a source/drain region;
exposing the substrate to a silicon-containing gas and an arsenic-containing gas to form a silicon arsenic alloy having an arsenic concentration of 4.5×10²¹ to 5×10²¹ atoms per cubic centimeter or greater on the source/drain region, wherein the silicon arsenic alloy has a carbon concentration of about 1×10¹⁷ atoms per cubic centimeter or greater; and
forming a transistor channel region on the silicon arsenic alloy.

8. The method of claim 7, wherein the silicon-containing gas comprises silane (SiH₄), disilane (Si₂H₆), trisilane (Si₃H₈), tetrasilane (Si₄H₁₀), monochlorosilane (MCS), dichlorosilane (DCS), trichlorosilane (TCS), hexachlorodisilane (HODS), octachlorotrisilane (OCTS), silicon tetrachloride (STC), or any combination thereof.

9. The method of claim 7, wherein the arsenic-containing gas comprises tertiary butyl arsine (TBAs) or arsine (AsH₃).

10. The method of claim 7, wherein the silicon-containing gas is disilane and the arsenic-containing gas is tertiary butyl arsine (TBAs).

11. The method of claim 7, wherein the silicon arsenic alloy has a carbon concentration of 1×10¹⁸ to 1×10²⁰ atoms per cubic centimeter.

12. A structure, comprising:
a substrate comprising a source region and a drain region;
a channel region disposed between the source region and the drain region;
a source drain extension region disposed laterally outward of the channel region, wherein the source drain extension region is a silicon arsenic alloy having an arsenic concentration of 4.5×10²¹ to 5×10²¹ atoms per cubic centimeter or greater and a carbon concentration of about 1×10¹⁷ atoms per cubic centimeter or greater; and
a gate region disposed above the channel region.

13. The structure of claim 12, wherein the silicon arsenic alloy has a carbon concentration of about 1×10¹⁸ to 1×10²⁰ atoms per cubic centimeter.

14. The structure of claim 12, wherein the silicon arsenic alloy is formed from an epitaxy process using a silicon-containing gas comprising silane (SiH₄), disilane (Si₂H₆), trisilane (Si₃H₈), tetrasilane (Si₄H₁₀), monochlorosilane (MCS), dichlorosilane (DCS), trichlorosilane (TCS), hexachlorodisilane (HODS), octachlorotrisilane (OCTS), silicon tetrachloride (STC), or any combination thereof, and an arsenic-containing gas comprising tertiary butyl arsine (TBAs) or arsine (AsH₃).

15. The structure of claim 14, wherein the silicon arsenic alloy is formed from an epitaxy process using disilane and TBAs.

16. A method of forming a germanium phosphide layer, comprising:
heating a silicon substrate disposed within a processing chamber having a chamber pressure of about 10 Torr to about 100 Torr;
exposing a surface of the substrate to a germanium-containing gas and a phosphorus-containing gas at a temperature of about 400 degrees Celsius or lower to form a germanium phosphide alloy having a phosphorus concentration of 7.5×10¹⁹ atoms per cubic centimeter or greater on the surface, wherein the phosphorus-containing gas is introduced into the processing chamber at a partial pressure of about 3 Torr to about 30 Torr.

17. The method of claim 16, wherein the germanium-containing gas comprises germane (GeH₄) or digermane (Ge₂H₆).

18. The method of claim 16, wherein the phosphorus-containing gas comprises phosphine (PH₃).

19. The method of claim 16, wherein exposing a surface of the substrate to a germanium-containing gas and a phosphorus-containing gas is performed at a temperature of about 350 degrees Celsius or lower.

20. The method of claim 16, wherein the mole ratio of phosphorus to germanium is between about 1:10 and about 1:40.
